(19) United States
(12) Patent Application Publication
(10) Pub. No.: US 2004/0149489 A1
(43) Pub. Date: Aug. 5, 2004

(54) Electronic module and method for assembling same

(76) Inventors: Frederic Ferrando, Kramsach/Tirol (AT); Philippe Clot, Les Charbonnieres (CH); Jean-Paul Racault, Saint-Antoine (FR)

Correspondence Address: Kurt D Van Tassel, Van Tassel & Associates, PO Box 2928, Bellaire, TX, 77401-2928, US

(21) Appl. No.: 10/477,277

(22) PCT Filed: Apr. 18, 2002
(86) PCT No.: PCT/CH02/00215

(30) Foreign Application Priority Data
May 11, 2001 (EP) 01810461.2

(51) Int. Cl. H05K 1/11; H01R 12/04

(52) U.S. Cl. 174/261

(57) ABSTRACT

The invention concerns an electronic module comprising: a printed circuit (10) including a flexible or semirigid substrate (12) provided with an array of strip conductors (14) deposited on each of its sides and with a plurality of contact pads (16) deposited on its upper side and connected to its array of conductor strips; at least an electronic chip (18), provided on its active surface with conductive bumps (20) respectively pressed on the contact pads; and a non-conductive adhesive layer (22) assembling the substrate and the chip. To avoid deformation of the module when the chip is being fixed by application of temperature and pressure, the substrate (12) is provided, on its lower side, with a plurality of reinforcing regions (24) arranged each opposite the contact pads (16).

The present invention relates to techniques for assembling integrated circuits, also commonly denoted electronic chips. It concerns, more particularly, an electronic module formed of an interconnection support or substrate and at least one chip fixed thereon. The invention also concerns a method for assembling such a module.

The increasingly extensive miniaturization of electronic chips cannot occur without a parallel adaptation of the techniques for mounting such components on their interconnection support.

One method, now recognized as very well suited to the aforementioned requirements, is the “Flip-Chip” method, in accordance with which the flipped over chips are secured via conductive protuberances, more commonly called “bumps”, onto the contact pads, more commonly called “pads” of the interconnection support.

The solution is seductive in principle but difficult to implement. In fact, it is necessary to ensure that the electric connection of the bumps on the pads is optimum and that the chip is securely fixed onto its substrate.

It is an object of the present invention to provide an electronic module whose structure and assembling method perfectly meet such requirements.

More precisely, the invention concerns an electronic module of the type including:

a printed circuit including a flexible or semi-rigid substrate provided with an array of conductive paths or strips deposited on each of its faces and a plurality of contact pads deposited on its top face and connected to its array of conductive paths,

at least one electronic chip provided, on its active face, with conductive bumps respectively applied onto said contact pads, and

a film of non-conductive adhesive assembling said substrate and said chip.

According to the invention, the substrate of a module as defined hereinbefore is provided, on its bottom face, with a plurality of reinforcing pads each arranged opposite one of said contact pads.

In an advantageous variant, the printed circuit includes, under its substrate, at least a second flexible or semi-rigid substrate provided with an array of conductive paths deposited on at least one of its faces, and a film of non-conductive adhesive assembling the two substrates. In this case, the second substrate is provided, on its bottom face, with a plurality of reinforcing pads each arranged opposite one of the contact pads.

In another advantageous variant, the printed circuit includes, under the flexible or semi-rigid substrate, a rigid substrate and a film of non-conductive adhesive assembling the two substrates.

Preferably, the reinforcing pads are made of copper and have substantially the same thickness as the conductive paths. Certain of these pads can advantageously be formed by portions of the conductive paths themselves.

The present invention also concerns a method for manufacturing the module defined hereinbefore, of the type consisting in depositing the film of non-conductive adhesive on the part of the printed circuit that has to receive the chip, in arranging the chip on the circuit such that its conductive bumps face the contact pads concerned, then in interconnecting them by raising the temperature of the assembly and exerting sufficient pressure on the chip for the bumps to pass through the film of adhesive and be crushed against the contact pads without any adhesive remaining between them.

According to the invention the temperature of the assembly is:

during a first time interval, kept constant at a first level allowing its viscosity to be reduced sufficiently for it to be spread as well as possible by capillary action in the space between the chip and the printed circuit,

during a second time interval, raised to a second level allowing acceleration of its polymerization,

kept at this second level during a third time interval, then

during a fourth time interval, brought back down to a third level.

Advantageously, said first, second and third temperature levels are respectively approximately 180° C., 220° C. and 200° C., whereas said first, second, third and fourth time intervals are respectively around 5, 2, 5 and 3 seconds.

Other features and advantages of the invention will appear from the following description, made with reference to the annexed drawing, in which:

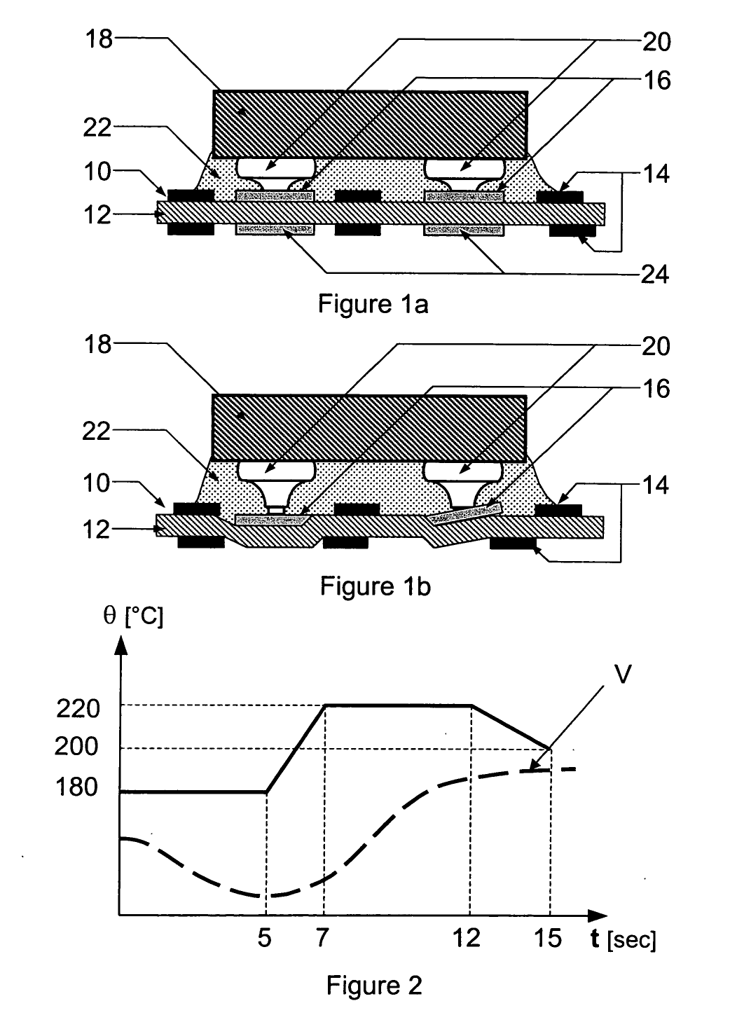

FIG. 1 shows a module using a single-layer flexible printed circuit, according to the invention in 1a and according to the prior art in 1b;

FIG. 2 is a diagram used to illustrate the method for assembling the module;

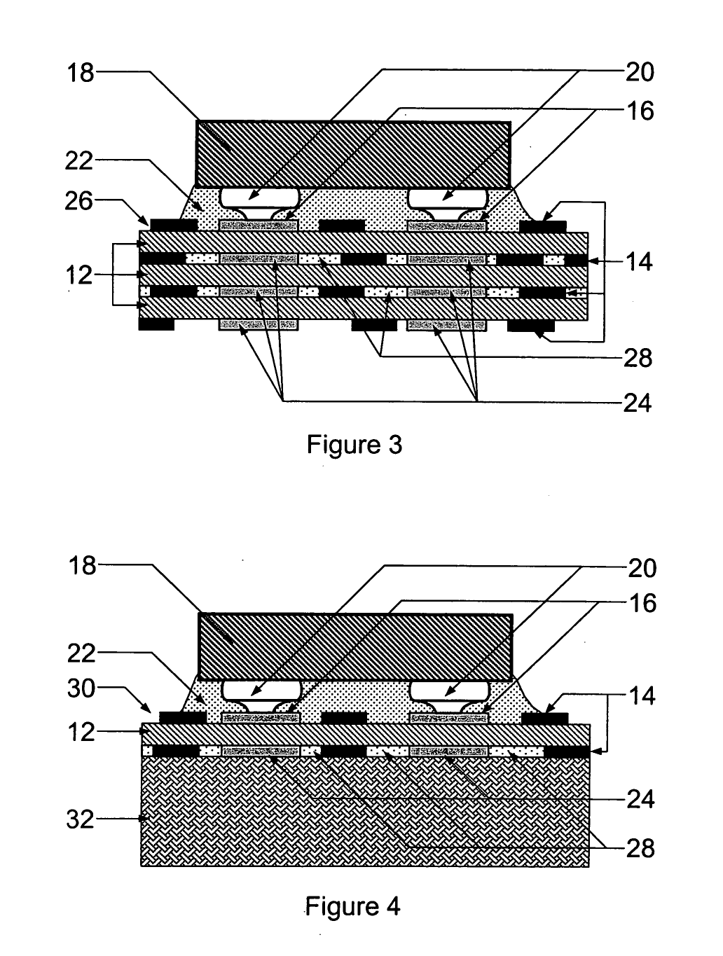

FIG. 3 shows a module using a multi-layered flexible printed circuit; and

FIG. 4 shows a module using a rigid printed circuit.

It will be specified that, in the drawing, the elements common to the various implementations of the invention are denoted by the same reference numbers.

The module of FIG. 1a has a flexible single-layer printed circuit 10 formed, in a conventional manner, by a polyimide substrate 12 having a thickness of 25 or 50 μm, for example, and two arrays of conductive copper paths 14 typically having a thickness of the order of 10 μm, deposited on each of the faces of the substrate.

On the top face of substrate 12, the conductive paths communicate with a plurality of contact pads 16, of substantially rectangular shape, only two of which appear in the Figure, for connecting various electronic components. In a conventional manner, these pads have a structure formed, starting from the substrate, of a copper layer, approximately 20 μm thick after remetallisation, a nickel layer, approximately 2 to 3 μm thick and a gold flash.

The Figure shows an integrated circuit or chip 18, which is deposited in “flip chip” mode on two of pads 16 of the top face of substrate 12 via conductive protuberances or bumps 20 arranged on its active face, in the shape of a mushroom, advantageously made of gold, and well known to those skilled in the art.

The fixing of bumps 20 onto pads 16 occurs directly without involving welding or bonding. The pads are fixed, as will be specified hereinafter, simply owing to the presence of a film of theoretically non-conductive adhesive 22 deposited beforehand on the substrate, in accordance with known techniques, which fills the space between chip 18 and printed circuit 10, securing them to each other and at the same time coating bumps 20 and pads 16. It will be noted here that the hardening of adhesive 22 by polymerization is accompanied by a decrease in its volume, which has the effect of drawing the bumps more strongly against the pads.

In order to position chip 18 so as to guarantee a good electrical connection between bumps 20 and pads 16, it is necessary to exert sufficiently strong pressure on the chip to crush the bumps against the pads. It will easily be understood, looking at FIG. 1b, that this action can cause a deformation of substrate 12 and consequently, irregular crushing of bumps 20, with interposition of adhesive. This results in a poor electrical connection between the bumps and pads.

In order to eliminate this risk and thus guarantee the regularity with which bumps 20 are crushed, the module according to the invention is provided, on the bottom face of substrate 12, as shown in FIG. 1a, with reinforcing pads or “counter-pads” 24, each arranged opposite a pad 16. These “counter-pads” 24 have substantially the same rectangular shape as pads 16. They have the same thickness as conductive paths 14 and, like the latter, are made of copper.

As a variant, and advantageously, certain of reinforcing pads 24 can be formed by portions of conductive paths 14 themselves, the course of which is adapted so as to make them pass just below pads 16.

The film of non-conductive adhesive 22 used to assemble the module is deposited beforehand on the part of printed circuit 10 that has to receive chip 18. The latter is then placed on the printed circuit so that its bumps 20 face the pads 16 concerned. As already mentioned, the interconnection is achieved by raising the temperature of the assembly and by exerting sufficient pressure on chip 18 for bumps 20 to pass through the film of adhesive and be crushed against pads 16.

The film of adhesive 22 thus plays a determining role to ensure, not only an optimum electrical contact between bumps 20 and pads 16, but also that chip 18 is properly secured to printed circuit 10.

In fact, during the operation of crushing bumps 20, non-conductive adhesive 22 has to be spread as well as possible in the entire space, without leaving any air bubbles detrimental to the resistance of the assembly and without any adhesive being interposed between the bumps and pads. The viscosity of the adhesive must, therefore, be very low at that moment.

It is then necessary to harden adhesive 22 by polymerization, which, for evident economical reasons, has to occur as quickly as possible.

Reference will now be made to FIG. 2, which illustrates the best way of varying the temperature of the enclosure in which the module is placed, to obtain the desired effects.

In this Figure, the curve representing the variation in temperature θ as a function of time t is in full lines, whereas the curve representing the variation in the resulting viscosity V of the adhesive is in dotted lines.

FIG. 2 shows that, during the first 5 seconds of the operation, temperature θ is maintained at around 180° C. This has the effect of approximately halving the viscosity V of the adhesive, which passes from a consistent state to a state allowing it to be spread as well as possible by capillary action in the space between the chip and the printed circuit.

The temperature then passes, during the next 2 seconds, from 180 to approximately 220° C., remains at this value for 5 seconds then, during the next 3 seconds, goes back down to 200° C. This allows the adhesive to polymerize very quickly, but without an excess, which would be detrimental to its resistance, to reach the solid state approximately 15 seconds after the start of the operation. By comparison, it would take 35 seconds to harden the adhesive if the temperature was maintained constantly at 180° C. for example. This time saving is particularly advantageous from an economical point of view.

Of course, these temperatures and these time durations are given purely by way of indication and can vary depending upon the type of adhesive used.

FIG. 3 shows a module according to the invention using a flexible multi-layered printed circuit 26, formed, in a conventional manner, by a stack of substrates 12, three in number in the Figure, provided with arrays of conductive paths 14. The stack is assembled by means of films of adhesive 28. In this case, in order to prevent the structure being deformed when chip 18 is being fixed by application of pressure and heating, as previously described, reinforcing pads 24 are arranged, opposite each of pads 16, not only on the rear face of the bottom substrate, but also between the different substrates.

Finally, FIG. 4 shows a module according to the invention using a rigid printed circuit 30 formed, also in a conventional manner, of a flexible substrate 12 provided with conductive paths 14 and a rigid substrate 32, made of epoxy resin, onto which substrate 12 is fixed by a film of adhesive 28. In this case too, in order to prevent flexible substrate 12 being deformed when chip 18 is being fixed, reinforcing pads 24 are arranged opposite each of pads 16, on the rear face of substrate 12.

1. Electronic module including:
a printed circuit (10, 26, 30) including a flexible or semi-rigid substrate (12) provided with an array of conductive paths (14) deposited on each of its faces and a plurality of contact pads (16) deposited on its top face and connected to its array of conductive paths,
at least one electronic chip (18) provided, on its active face, with conductive bumps (20) respectively applied onto said contact pads, and
a film of non-conductive adhesive (22) assembling said substrate and said chip,
characterized in that the substrate (12) is provided, on its bottom face, with a plurality of reinforcing pads (24) each arranged opposite one of said contact pads (16).

2. Module according to claim 1, characterized in that said printed circuit (26) includes, under said substrate (12), at least a second flexible or semi-rigid substrate (12) provided with an array of conductive paths (14) deposited on at least one of its faces, and a film of non-conductive adhesive (28) assembling the two substrates, and in that the second substrate is provided, on its bottom face, with a plurality of reinforcing pads (24) each arranged opposite one of said contact pads (16).

3. Module according to claim 1, characterized in that said printed circuit (30) includes, under the flexible or semi-rigid substrate (12), a rigid substrate (32) and a film of non-conductive adhesive (28) assembling the two substrates.

4. Module according to any of claims 1 to 3, characterized in that said reinforcing pads (24) are made of copper.

5. Module according to claim 4, characterized in that said reinforcing pads (24) have substantially the same thickness as the conductive paths (14).

6. Module according to claim 4, characterized in that said reinforcing pads (24) are formed by portions of the conductive paths (14) themselves.

7. Method for manufacturing the module according to claim 1, consisting in depositing the film of non-conductive adhesive (22) on the part of the printed circuit (10, 26, 30) that has to receive the chip (18), in arranging the chip on the circuit such that its bumps (20) face the contact pads (16) concerned, then in interconnecting them by raising the temperature of the assembly and exerting sufficient pressure on the chip for said bumps to pass through the film of adhesive (22) and be crushed against the pads (16) without any adhesive remaining between them, characterized in that the temperature is:
during a first time interval, kept constant at a first level allowing its viscosity to be reduced sufficiently for it to be spread as well as possible by capillary action in the space between the chip and the printed circuit,
during a second time interval, raised to a second level allowing acceleration of its polymerization,
kept at this second level during a third time interval, then
during a fourth time interval, brought back down to a third level.

8. Method according to claim 7, characterized in that said first, second and third temperature levels are respectively approximately 180° C., 220° C. and 200° C.

9. Method according to claim 8, characterized in that said first, second, third and fourth time intervals are respectively approximately 5, 2, 5 and 3 seconds.
